(19) United States
(12) Patent Application Publication
(10) Pub. No.: US 2016/0064474 A1
(43) Pub. Date: Mar. 3, 2016

(54) SEMICONDUCTOR DEVICE AND METHOD FOR MANUFACTURING THE SAME

(71) Applicant: ELECTRONICS AND TELECOMMUNICATIONS RESEARCH INSTITUTE, Daejeon (KR)

(72) Inventor: Dongwoo SUH, Daejeon (KR)

(73) Assignee: ELECTRONICS AND TELECOMMUNICATIONS RESEARCH INSTITUTE, Daejeon (KR)

(21) Appl. No.: 14/634,132

(22) Filed: Feb. 27, 2015

(30) Foreign Application Priority Data
Aug. 27, 2014 (KR) 10-2014-0112400

(51) Int. Cl. H01L 29/06; H01L 31/0352; H01L 21/3105; H01L 31/109; H01L 31/18; H01L 21/02; H01L 29/165; H01L 31/028

(52) U.S. Cl. CPC H01L 29/068; H01L 29/0676; H01L 29/165; H01L 31/035227; H01L 31/028; H01L 31/109; H01L 31/1804; H01L 21/02532; H01L 21/02603; H01L 21/0262; H01L 21/31053

(57) ABSTRACT

A semiconductor device includes: a substrate doped with a first conductive type;
a first nanowire protruding on the substrate in a first direction and including a first core and a first shell; and an electrode being on the first nanowire and directly contacting a top surface of the first core, wherein the first shell covers a sidewall of the first core;
the first shell includes a first semiconductor; and the first core includes a second semiconductor having a different bandgap than the first semiconductor.

### CROSS-REFERENCE TO RELATED APPLICATIONS

This U.S. non-provisional patent application claims priority under 35 U.S.C. §119 of Korean Patent Application No. 10-2014-0112400, filed on Aug. 27, 2014, the entire contents of which are hereby incorporated by reference.

### BACKGROUND OF THE INVENTION

The present invention disclosed herein relates to a semiconductor device and a method of manufacturing the same, and more particularly, to a semiconductor device having a nanowire structure and a method of manufacturing the same.

A nanowire has a rod shape having an intermediate size of a macroscopic size and a microscopic size in terms of size and generally has a quasi-one-dimensional structure with a diameter of less than 100 nm A semiconductor nanowire has various applications in electronic device and optical device fields due to quantum confinement and ballistic transport characteristics.

### SUMMARY OF THE INVENTION

The present invention provides a semiconductor device capable of improving a charge transfer speed and increasing a device current density.

The present invention also provides a semiconductor device manufacturing method for improving a charge transfer speed and increasing a device current density.

Embodiments of the present invention provide semiconductor devices including: a substrate doped with a first conductive type; a first nanowire protruding on the substrate in a first direction and including a first core and a first shell; and an electrode being on the first nanowire and directly contacting a top surface of the first core, wherein the first shell covers a sidewall of the first core; the first shell includes a first semiconductor; and the first core includes a second semiconductor having a different bandgap than the first semiconductor.

In some embodiments, a top surface and a bottom surface of the first shell may be coplanar with the top surface and a bottom surface of the first core, respectively.

In other embodiments, the semiconductor devices may further include: a first insulation layer covering the top surface of the substrate and a sidewall of the first nanowire; and a second insulation layer covering the first insulation layer.

In still other embodiments, the first nanowire may be undoped or intrinsic in terms of electrical polarity.

In even other embodiments, the first core may be connected to the substrate to form a p-n junction or an n-p junction.

In yet other embodiments, the semiconductor devices may further include a second nanowire protruding on the substrate in the first direction and interposed between the substrate and the first nanowire, wherein the second nanowire may overlap the first nanowire from the plane perspective; and the second nanowire may include the second semiconductor or a third semiconductor different from the second semiconductor.

In further embodiments, a diameter of the first core may be substantially identical or similar to a diameter of the second nanowire.

In still further embodiments, the first core and the second nanowire may constitute one body.

In even further embodiments, the semiconductor device may further include a third nanowire protruding on the substrate in the first direction, interposed between the substrate and the second nanowire, and including a second core directly contacting the second nanowire and a second shell, wherein the third nanowire may overlap the first and second nanowires from the plane perspective; the second shell may cover a sidewall of the second core; the second shell may include the second semiconductor or a fourth semiconductor different from the second semiconductor; the second core may include the first semiconductor or a fifth semiconductor having a different bandgap than the fourth semiconductor; and the second core may have the first conductive type by a heterojunction of the first semiconductor and the second semiconductor or a heterojunction of the fourth semiconductor and the fifth semiconductor.

In yet other embodiments, an angle formed between the first direction and a top surface of the substrate may be vertical or close to verticality.

In further embodiments, the first core may have a second conductive type by a heterojunction of the first semiconductor and the second semiconductor

In other embodiments of the present invention, semiconductor devices include: a substrate doped with a first conductive type; first, second, third, and fourth nanowires sequentially stacked on the substrate; and an electrode disposed on the fourth nanowire to be electrically connected to the substrate, wherein each of the first, second, third, and fourth nanowires includes the same or different semiconductor; the second nanowire includes a first core having a second conductive type and a first shell covering a sidewall of the first core; and the fourth nanowire includes a second core having the first conductive type and a second shell covering a sidewall of the second core.

In some embodiments, the first core may have the second conductive type by a heterojunction with the first shell; the second core may have the first conductive type by a heterojunction with the second shell; and the first, second, third, and fourth nanowires may be undoped or intrinsic in terms of electrical polarity.

In still other embodiments of the present invention, provided are methods of manufacturing a semiconductor device. The methods include: providing a substrate doped with a first conductive type; forming a first core, on the substrate, extending in a first direction of which angle formed with a top surface of the substrate is vertical or close to verticality; and forming a first shell extending from a sidewall of the first core in a second direction parallel to the top surface of the substrate and perpendicular to the first direction, wherein the forming of the first shell includes glowing a first semiconductor to cover a sidewall of the first core without impurity doping; and the forming of the first core includes growing, on the substrate, a second semiconductor having a different bandgap than the first semiconductor without impurity doping.

In some embodiments, the forming of the first core and the first shell may include growing the first core and the first shell into a Vapor Liquid Solid (VLS) mechanism through a chemical vapor deposition process.

In other embodiments, the forming of the first insulation layer covering the top surface of the substrate and the sidewall of the first shell may include: forming a second insulation layer covering the first insulation layer; planarizing the second insulation layer to allow a top surface of the second insulation layer to be coplanar with a top surface of the first core and a top surface of the first shell; and forming an electrode on the second insulation layer to be electrically connected to the first core.

In still other embodiments, the methods may further include forming a first nanowire extending in the first direction on the substrate, wherein the forming of the first core may include growing the second semiconductor in the first direction on the first nanowire.

In even other embodiments, the methods may further include: forming a first insulation layer covering a top surface of the substrate and a sidewall of the first nanowire; forming a second insulation layer covering the first insulation layer; planarizing the second insulation layer to allow a top surface of the second insulation layer to be coplanar with a top surface of the first nanowire, wherein the forming of the first core may include growing the second semiconductor in the first direction, on the exposed top surface of the first nanowire.

In yet other embodiments, the forming of the first shell may include growing the first semiconductor in the second direction on a partial sidewall of the first core and the partial sidewall of the first core is a sidewall of an upper portion of the first core.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a plan view of a semiconductor device according to an embodiment of the present invention;

FIG. 2 is a sectional view of a semiconductor device taken along a line I-I′ of FIG. 1 according to an embodiment of the present invention;

FIGS. 3A and 3B describe a method of manufacturing a semiconductor device according to an embodiment of the present invention and are sectional views taken along a line I-I′ of FIG. 1;

FIG. 4 is a sectional view of a semiconductor device taken along a line I-I′ of FIG. 1 according to another embodiment of the present invention;

FIGS. 5A to 5c describe a method of manufacturing a semiconductor device according to another embodiment of the present invention and are sectional views taken along a line I-I′ of FIG. 1;

FIG. 6 is a sectional view of a semiconductor device taken along the line I-I′ of FIG. 1 according to another embodiment of the present invention;

FIGS. 7A and 7B describe a method of manufacturing a semiconductor device according to another embodiment of the present invention and are sectional views taken along a line I-I′ of FIG. 1;

FIG. 8 is a sectional view of a semiconductor device taken along the line I-I′ of FIG. 1 according to another embodiment of the present invention;

FIGS. 9A to 9C describe a method of manufacturing a semiconductor device according to another embodiment of the present invention and are sectional views taken along a line I-I′ of FIG. 1;

FIG. 10 is a sectional view of a semiconductor device taken along the line I-I′ of FIG. 1 according to another embodiment of the present invention; and

FIG. 11 is a sectional view of a semiconductor device taken along the line I-I′ of FIG. 1 according to another embodiment of the present invention.

### DETAILED DESCRIPTION OF PREFERRED EMBODIMENTS

In order to understand the configuration and effect of the present invention, preferred embodiments of the present invention are described with reference to the accompanying drawings. However, the present invention is not limited to embodiments set forth herein and may be implemented in various forms and with various modifications. Rather, these embodiments are provided so that this disclosure will be thorough and complete, and will fully convey the scope of the present invention to those skilled in the art.

In the specification, it will be understood that when one element is referred to as being ‘on’ another element, it can be directly on the other element, or intervening elements may also be present. In the figures, moreover, the dimensions of elements are exaggerated for clarity of illustration. Like reference numerals refer to like elements throughout the specification.

Additionally, the embodiment in the detailed description will be described with sectional and/or plan views as ideal exemplary views of the present invention. Also, in the figures, the dimensions of layers and regions are exaggerated for clarity of illustration. Areas exemplified in the drawings have general properties, and are used to illustrate a specific shape of a semiconductor package region. Thus, this should not be construed as limited to the scope of the present invention. Also, though terms like a first and a second are used to describe various members, components, regions, layers, and/or portions in various embodiments of the present invention, the members, components, regions, layers, and/or portions are not limited to these terms. These terms are used only to discriminate one region or layer from another region or layer. An embodiment described and exemplified herein includes a complementary embodiment thereof.

In the following description, the technical terms are used only for explaining specific embodiments while not limiting the present invention. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

### Embodiment 1

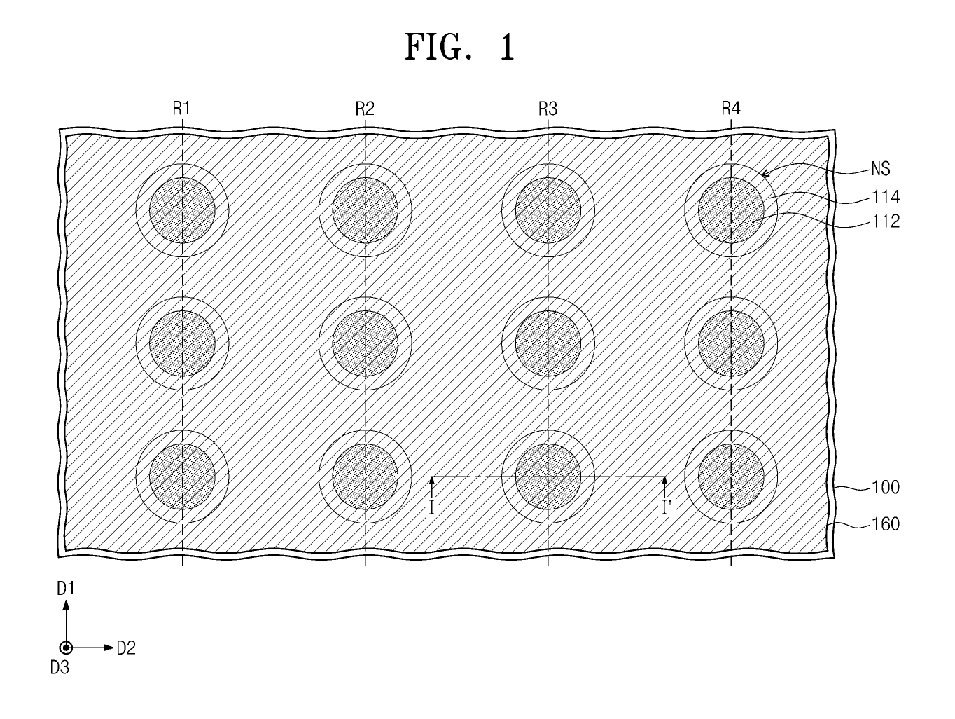

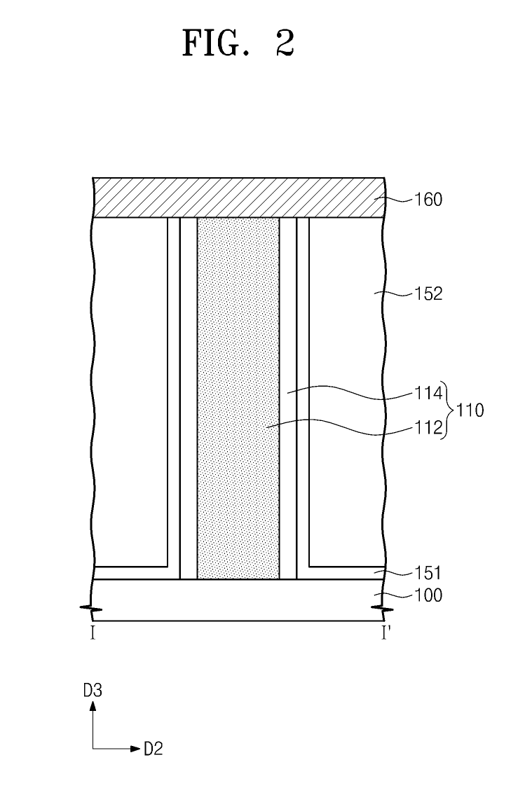

FIG. 1 is a plan view of a semiconductor device according to an embodiment of the present invention. FIG. 2 is a sectional view of a semiconductor device taken along a line I-I′ of FIG. 1 according to an embodiment of the present invention.

Referring to FIGS. 1 and 2, a substrate 100 may be provided. The substrate 100 may be a semiconductor substrate including silicon, germanium, and silicon-germanium or a compound semiconductor substrate. In more detail, the substrate 100 may have an arbitrary semiconductor based structure with a silicon surface. Such a semiconductor based structure may include silicon, silicon on insulator (SOI), or a silicon epitaxial layer supported by a semiconductor structure. The substrate 100 may be a substrate doped with a first conductive type impurity. The first conductive type may include an n type or a p type. As one example, the substrate 100 may be doped with an n type impurity to have an n type. Although not shown in the drawing, an external voltage (for example, a ground voltage) may be applied to the substrate 100.

A plurality of nanowire structures NS may be disposed on the substrate 100. The nanowire structures NS may be arranged in a first direction D1 parallel to the top surface of the substrate 100 to form first to fourth rows R1 to R4. The first to fourth rows R1 to R4 may be spaced apart from each other in a second direction D2 parallel to the top surface of the substrate 100 and perpendicular to the first direction D1. The nanowire structures NS may include more rows on the substrate 100 in addition to the first to fourth rows R1 to R4 but due to the limit on the size of the drawing, only the first to fourth rows R1 to R4 are described in this embodiment.

Each of the nanowire structures NS may protrude in a third direction D3 on the top surface of the substrate 100. The third direction D3 may be a direction perpendicular to the top surface of the substrate 100 and also perpendicular to the both the first direction D1 and the second direction D2. Or, the third direction D3 may be a direction of which angle formed with the top surface of the substrate 100 is close to the verticality.

In this embodiment, each of the nanowire structures NS may include a first nanowire 110. The first nanowire 110 may include a first core 112 and a first shell 114. The first core 112 may have a cylindrical form extending from the top surface of the substrate 100 in the third direction D3. The first shell 114 may have a pipe shape covering the sidewall of the first core 112 and extending from the top surface of the substrate 100 in the third direction D3. The top surface of the first shell 114 may be coplanar with the top surface of the first core 112. The bottom surface of the first shell 114 may be coplanar with the bottom surface of the first core 112. From the plane perspective, the first core 112 may have a circular form and the first shell 114 may have a donut shape surrounding the frame of the first core 112.

The first shell 114 may include a first intrinsic semiconductor. The first intrinsic semiconductor may be a high-purity semiconductor with little or no impurities. In more detail, the first intrinsic semiconductor may include an elemental semiconductor such as Si and Ge. Or, the first intrinsic semiconductor may include a compound semiconductor such as GaAs, GaP, GaSb, InP, InAs, InSb, ZnSe, ZnTe, CdSe, or CdTe. The first core 112 may include a second intrinsic semiconductor. The second intrinsic semiconductor may have a different bandgap than the first intrinsic semiconductor. Besides that, the second intrinsic semiconductor may be described identical to the first intrinsic semiconductor.

The first core 112 and the first shell 114 may not be doped with impurities. However, the first core 112 may have a second conductive type opposite to the first conductive type by the first shell 114. That is, the first core 112 may have the second conductive type by a staggered heterojunction of the first intrinsic semiconductor and the second intrinsic semiconductor.

In more detail, the second intrinsic semiconductor of the first core 112 may have a different bandgap and work function value than the first intrinsic semiconductor of the first shell 114. Accordingly, the first core 112 and the first shell 114 may contact each other at the sidewall of the first core 112 to have staggered heterojunction characteristics. Through the staggered heterojunction characters, it is possible to adjust a final Fermi energy level position. Before two intrinsic semiconductors having different bandgaps form a junction, since they are not doped, the Fermi energy level of each of the two intrinsic semiconductors may be disposed at the middle of a bandgap. Moreover, the two intrinsic semiconductors may be selected with a combination of intrinsic semiconductors showing a staggered heterojunction structure when they form a junction. When the two intrinsic semiconductors form a junction, a Fermi energy level may move to close to the maximum energy of a valence band or the minimum energy of a valence band. Thus, at least one of the two intrinsic semiconductors may have a p-type or an n-type. That is, without artificial impurity doping, at least one of the two intrinsic semiconductors may have a doping effect.

In this embodiment, the second intrinsic semiconductor of the first core 112 may include Ge and the first intrinsic semiconductor of the first shell 114 may include Si. At this point, the first core 112 may have a p-type by a staggered heterojunction of Ge and Si. In this case, the substrate 100 may be a substrate doped with an n-type. On the other hand, the second intrinsic semiconductor of the first core 112 may include Si and the first intrinsic semiconductor of the first shell 114 may include Ge. At this point, the first core 112 may have an n-type by a staggered heterojunction of Si and Ge. In this case, the substrate 100 may be a substrate doped with a p-type.

In the case of a nanowire vertically disposed on a substrate, there are several issues with a process for doping an impurity into a partial area of the nanowire. For example, by doping an impurity on a nanowire, an impurity segregation or a non-uniform doping distribution may occur. On the other hand, a semiconductor device according to this embodiment may provide a doping effect of the second conductive type to the first core 112 without an artificial impurity doping on the first nanowire 110. Accordingly, in relation to a vertical type nanowire, it is possible to solve the issues of the above-mentioned impurity segregation or non-uniform doping distribution.

A first insulation layer 151 covering the top surface of the substrate 100 and the sidewall of the first nanowire 110 may be disposed. Although not shown in the drawing, the first insulation layer 151 may cover all the sidewalls of the nanowire structures NS on the substrate 100. The first insulation layer 151 may cover the sidewall of the first shell 114. The first core 112 may be spaced apart from the first insulation layer 151 with the first shell 114 therebetween. The top surface of the first insulation layer 151 may be coplanar with the top surface of the first core 112 and the top surface of the first shell 114. The first insulation layer 151 may include a silicon oxide layer, a silicon oxide nitride layer, or a metal oxide layer such as an aluminum oxide layer.

A second insulation layer 152 covering the first insulation layer 151 may be disposed. Although not shown in the drawing, the second insulation layer 152 may fill an empty space between the nanowire structures NS. The top surface of the second insulation layer 152 may be coplanar with the top surface of the first core 112 and the top surface of the first shell 114. The second insulation layer 152 may include a silicon oxide layer, a silicon oxide nitride layer, a metal oxide layer such as an aluminum oxide layer, or a low-k oxide layer. As one example, the low-k oxide layer may include a silicon oxide layer doped with carbon such as SiCOH.

An electrode 160 may be disposed on the first nanowire 110. That is, the electrode 160 may be disposed on the second insulation layer 152 and the nanowire structures NS. The electrode 160 may contact the top surface of the first core 112 directly and thus, the electrode 160 may be electrically connected to the first core 112.

In this embodiment, the bottom surface of the first core 112 may contact the top surface of the substrate 100 directly and thus, the first core 112 may be electrically connected to the substrate 100. Accordingly, the substrate 100 may be electrically connected to the electrode 160 through the first core 112. As described above, the substrate 100 may be doped with the first conductive type and the first core 112 may have a doping effect of the second conductive type. Thus, a p-n junction or an n-p junction may be formed at the interface between the substrate 100 and the first core 112.

Nanowire structures NS according to embodiments of the present invention may form a diode between the substrate 100 and the electrode 160. The nanowire structures NS may improve a charge transfer speed by ballistic transport mechanism. Additionally, a device current density may be increased by reducing a recombination loss occurring during a charge transmission process.

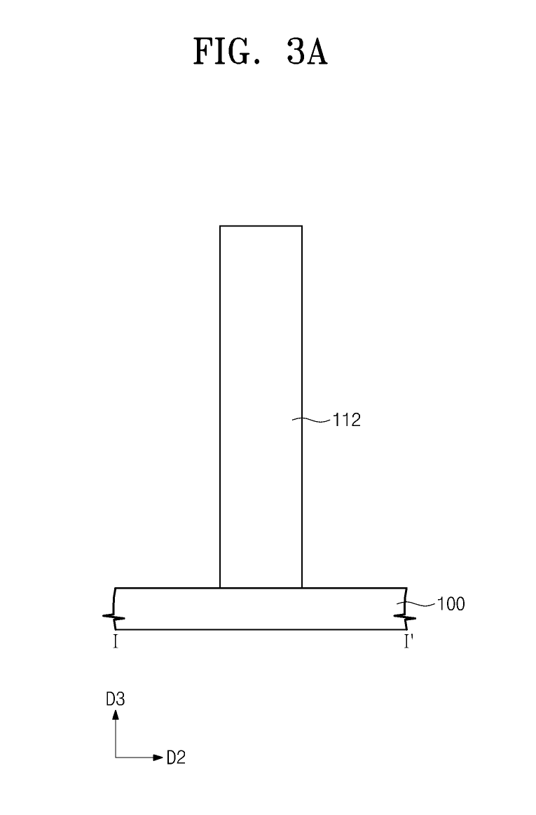

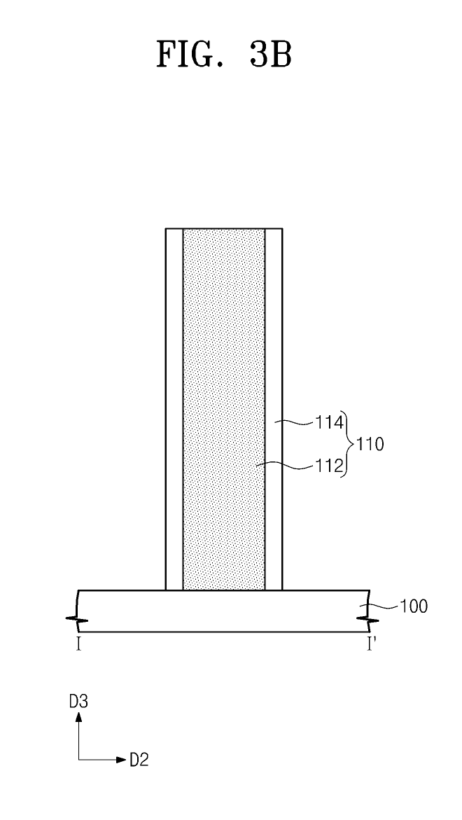

FIGS. 3A and 3B describe a method of manufacturing a semiconductor device according to an embodiment of the present invention and are sectional views taken along the line I-I′ of FIG. 1.

Referring to FIGS. 1 and 3a, a substrate 100 doped with a first conductive type may be provided. The substrate 100 may be a semiconductor substrate including silicon, germanium, and silicon-germanium or a compound semiconductor substrate. In more detail, the substrate 100 may have an arbitrary semiconductor based structure with a silicon surface. The substrate 100 may be doped with a first conductive type impurity. The first conductive type may include an n type or a p type. As one example, the substrate 100 may be doped with an n type impurity to have an n type. Although not shown in the drawing, an external voltage may be applied to the substrate 100.

A first core 112 extending in a third direction D3 perpendicular to the top surface of the substrate 100 may be formed on the substrate 100. The third direction D3 may be a direction of which angle formed with the top surface of the substrate 100 is close to the verticality. The first core 112 may be a nanowire including a second intrinsic semiconductor. The second intrinsic semiconductor may be a high-purity semiconductor with little or no impurities. In more detail, the second intrinsic semiconductor may include an elemental semiconductor such as Si and Ge. Or, the second intrinsic semiconductor may include a compound semiconductor such as GaAs, GaP, GaSb, InP, InAs, InSb, ZnSe, ZnTe, CdSe, or CdTe. The first core 112 may have a cylindrical form extending in the third direction D3. While or after the first core 112 is formed, an impurity doping process may not be performed.

As one example, the first core 112 may grow into a Vapor Liquid Solid (VLS) mechanism through a chemical vapor deposition process. The VLS mechanism may proceed in a chemical vapor deposition process and may improve a crystal growth rate through a direct gas adsorption on a solid surface. Briefly, the VSL process introduces a rapidly adsorbing supersaturated liquid and grows crystals vertically by using a crystal nucleus between liquid and solid. At this point, a source gas for crystal growth may be introduced continuously and may include a gas based on the second intrinsic semiconductor element. For example, the second intrinsic semiconductor is Ge, the source gas may be germane (GeH₄). When the second intrinsic semiconductor is Si, the source gas may be silane (SiH₄).

Referring to FIGS. 1 and 3B, a first shell 114 may be formed from the sidewall of the first core 112. The first shell 114 may grow in directions parallel to the top surface of the substrate 100. That is, the growth direction of the first shell 114 may include both a first direction D1 and a second direction D2 perpendicular to the third direction D3 that is the growth direction of the first core 112 and parallel to the top surface of the substrate 100 at the same time. As a result, the first shell 114 may be formed with a pipe shape covering the sidewall of the first core 112 and extending from the top surface of the substrate 100 in the third direction D3. While or after the first shell 114 is formed, an impurity doping process may not be performed. The first shell 114 may include a first intrinsic semiconductor. The first intrinsic semiconductor may have a different bandgap than the second intrinsic semiconductor. Besides that, the first intrinsic semiconductor may be described identical or similar to the second intrinsic semiconductor.

The first shell 114 may grow into a VLS mechanism through a chemical vapor deposition process. The formation process of the first shell 114 may be described identical or similar to the formation process of the first core 112. However, unlike the formation process of the first core 112, the formation process of the first shell 114 may use a gas based on the first intrinsic semiconductor element as a source gas. For example, when germane (GeH₄) is used as a source gas in the formation process of the first core 112, silane (SiH₄) may be used as a source gas in the formation process of the first shell 114. When silane (SiH₄) is used as a source gas in the formation process of the first core 112, germane (GeH₄) may be used as a source gas in the formation process of the first shell 114.

As the first shell 114 is formed, the first core 112 may have a second conductive type opposite to the first conductive type. Due to a staggered heterojunction of the second intrinsic semiconductor of the first core 112 and the first intrinsic semiconductor of the first shell 114, the first core 112 has the second conductive type. That is, without an artificial impurity doping process, a doping effect may occur from the first core 112. Accordingly, in relation to a vertical type nanowire, it is possible to solve the issues of an impurity segregation or a non-uniform doping distribution due to an impurity doping process. As one example, when the formed first core 112 includes Ge and the formed first shell 114 includes Si, the first core 112 may have a p-type. In this case, the substrate 100 may be doped with an n-type. On the other hand, when the first core 112 includes Si and the first shell 114 includes Ge, the first core 112 may have an n-type. In this case, the substrate 100 may be doped with a p-type.

The formed first core 112 and the formed first shell 114 may define a first nanowire 110. Although only the formation process of the first nanowire 110 is shown through FIGS. 3A and 3B, a plurality of nanowire structures NS may be formed on the substrate 100 at the same time. Each of the nanowire structures NS may include the first nanowire 110.

Again, referring to FIGS. 1 and 2, a first insulation layer 151 covering the top surface of the substrate 100 and the sidewall of the first shell 114 may be formed. Then, a second insulation layer 152 covering the first insulation layer 151 may be formed. The first insulation layer 151 may be conformally deposited on the result of FIG. 3B. The first insulation layer 151 may cover all the top surface of the substrate 100 and the nanowire structures NS. The first insulation layer 151 may include a silicon oxide layer, a silicon oxide nitride layer, or a metal oxide layer such as an aluminum oxide layer. Then, a second insulation layer 152 covering the first insulation layer 151 may be formed. The second insulation layer 152 may include a silicon oxide layer, a silicon oxide nitride layer, a metal oxide layer such as an aluminum oxide layer, or a low-k oxide layer. As one example, the low-k oxide layer may include a silicon oxide layer doped with carbon such as SiCOH. The second insulation layer 152 and the first insulation layer 151 may be planarized. Through the planarization process, the top surface of the second insulation layer 152 may be coplanar with the top surface of the first insulation layer 151, the top surface of the first core 112, and the top surface of the first shell 114. Furthermore, the top surface of the first core 112 may be exposed.

Then, an electrode 160 may be formed on the second insulation layer 152. The electrode 160 may contact the top surface of the first core 112 directly and thus, the electrode 160 may be electrically connected to the first core 112.

### Embodiment 2

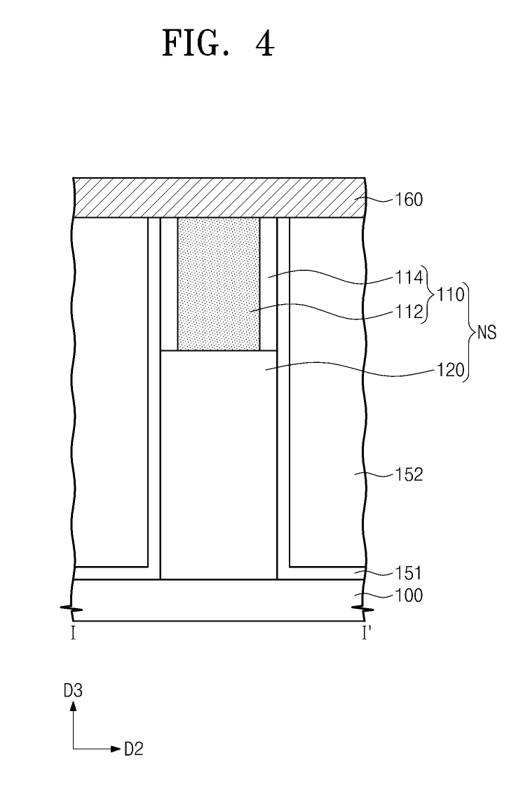

FIG. 4 is a sectional view of a semiconductor device taken along the line I-I′ of FIG. 1 according to another embodiment of the present invention. In this embodiment, the detailed descriptions of the technical features overlapping those described with reference to FIGS. 1 and 2 are omitted and the differences will be described in detail. It is possible to provide the same reference numerals with respect to the same configuration of the above-mentioned semiconductor device according to an embodiment of the present invention.

Referring to FIGS. 1 and 4, a plurality of nanowire structures NS may be disposed on the substrate 100 having a first conductive type. Each of the nanowire structures NS may include a sequentially-stacked second nanowire 120 and first nanowire 110. The second nanowire 120 may have a cylindrical form extending in a third direction D3 on the top surface of the substrate 100. The third direction D3 may be a direction perpendicular to the top surface of the substrate 100. Or, the third direction D3 may be a direction of which angle formed with the top surface of the substrate 100 is close to the verticality. The second nanowire 120 may be interposed between the substrate 100 and the first nanowire 110.

Unlike the first nanowire 110, the second nanowire 120 may not include an additional core and shell. That is, the second nanowire 120 may be formed of one intrinsic semiconductor. The second nanowire 120 may include the same second intrinsic semiconductor as the first core 112. Or, the second nanowire 120 may include a different third intrinsic semiconductor than the second intrinsic semiconductor. In more detail, the third intrinsic semiconductor may include an elemental semiconductor such as Si and Ge. Or, the third intrinsic semiconductor may include a compound semiconductor such as GaAs, GaP, GaSb, InP, InAs, InSb, ZnSe, ZnTe, CdSe, or CdTe.

The first nanowire 110 may extend from the top surface of the second nanowire 120 in the third direction D3. The first nanowire 110 may include a first core 112 and a first shell 114 covering the sidewall of the first core 112. The diameter of the first nanowire 110 may be substantially identical to the diameter of the second nanowire 120. However, the diameter of the first core 112 may be less than the diameter of the second nanowire 120. From the plane perspective, the first nanowire 110 may overlap the second nanowire 120 vertically.

The first insulation layer 151 may cover both the sidewall of the first nanowire 110 and the sidewall of the second nanowire 120. The electrode 160 may contact the top surface of the first core 112 directly and thus, the electrode 160 may be electrically connected to the first core 112. Furthermore, the substrate 100 may be electrically connected to the electrode 160 through the second nanowire 120 and the first core 112. Thus, a p-i-n junction or an n-i-p junction may be formed through an electrical connection between the substrate 100, the second nanowire 120, and the first core 112. The second nanowire 120 may form a depletion region between the substrate 100 and the first core 112.

In this embodiment, other omitted descriptions may be identical to the descriptions of FIGS. 1 and 2.

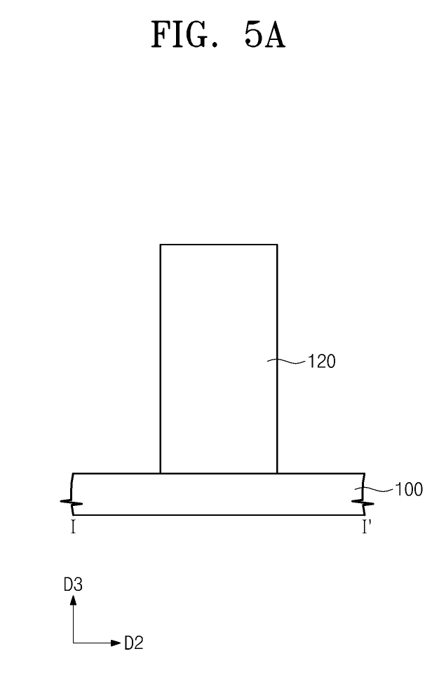

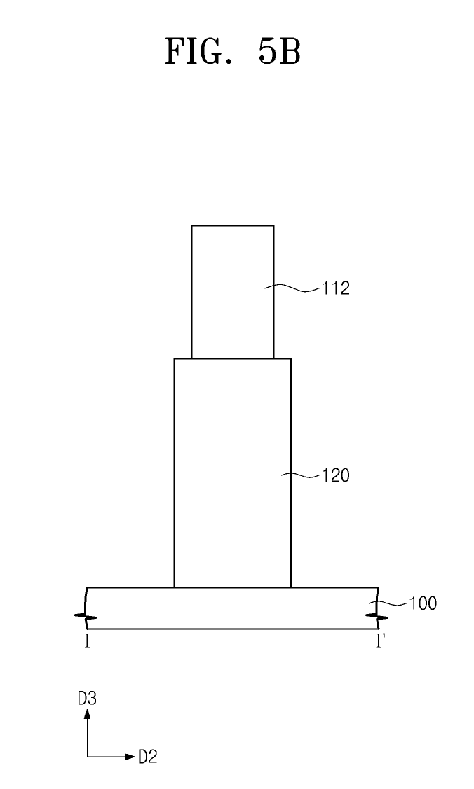

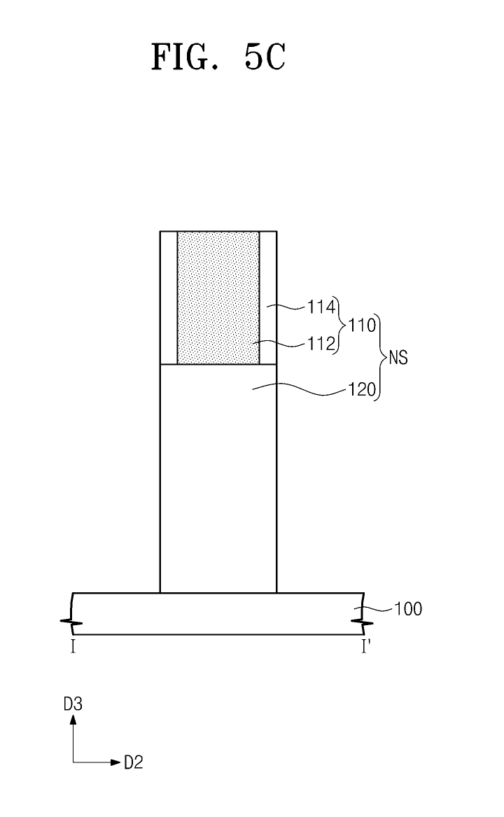

FIGS. 5A and 5c describe a method of manufacturing a semiconductor device according to another embodiment of the present invention and are sectional views taken along the line I-I′ of FIG. 1. In this manufacturing method of this embodiment, the detailed descriptions of the technical features overlapping those of the manufacturing method described with reference to FIGS. 3A and 3B are omitted and the differences will be described in detail.

Referring to FIGS. 1 and 5a, a substrate 100 doped with a first conductive type may be provided. A second nanowire 120 extending in a third direction D3 perpendicular to the top surface of the substrate 100 may be formed on the substrate 100. The third direction D3 may be a direction of which angle formed with the top surface of the substrate 100 is close to the verticality. The second nanowire 120 may have a cylindrical form extending in a third direction D3 on the top surface of the substrate 100.

The second nanowire 120 may include the same second intrinsic semiconductor as a first core 112 described later. Or, the second nanowire 120 may include a different third intrinsic semiconductor than the second intrinsic semiconductor. In more detail, the third intrinsic semiconductor may include an elemental semiconductor such as Si and Ge. Or, the third intrinsic semiconductor may include a compound semiconductor such as GaAs, GaP, GaSb, InP, InAs, InSb, ZnSe, ZnTe, CdSe, or CdTe.

As one example, the second nanowire 120 may grow into a VLS mechanism through a chemical vapor deposition process. For example, when the second intrinsic semiconductor or the third intrinsic semiconductor is Ge, a source gas may be germane (GeH₄). While or after the second nanowire 120 is formed, an impurity doping process may not be performed.

Referring to FIGS. 1 and 5B, the first core 112 extending in the third direction D3 may be formed on the second nanowire 120. The first core 112 may have a cylindrical form extending in the third direction D3 on the top surface of the second nanowire 120. The diameter of the formed first core 112 may be less than the diameter of the second nanowire 120. From the plane perspective, the first nanowire 110 may overlap the second nanowire 120 vertically. The first core 112 may grow into a VLS mechanism through a chemical vapor deposition process.

Referring to FIGS. 1 and 5C, a first shell 114 may be formed from the sidewall of the first core 112. The first shell 114 may grow in directions parallel to the top surface of the substrate 100. As a result, the first shell 114 may be formed with a pipe shape covering the sidewall of the first core 112 and extending from the top surface of the second nanowire 120 in the third direction D3. As the first shell 114 is formed, the first core 112 may have a second conductive type opposite to the first conductive type. Due to a staggered heterojunction of the second intrinsic semiconductor of the first core 112 and the first intrinsic semiconductor of the first shell 114, the first core 112 has the second conductive type.

The formed first core 112 and the formed first shell 114 may define a first nanowire 110. The sequentially-stacked second nanowire 120 and first nanowire 110 may define a nanowire structure NS. Although only the formation process of the one nanowire structure NS is shown through FIGS. 5A to 5C, a plurality of nanowire structures NS may be formed on the substrate 100 at the same time.

Again, referring to FIGS. 1 and 4, a first insulation layer 151 covering the top surface of the substrate 100, the sidewall of the second nanowire 120, and the sidewall of the first shell 114 may be formed. Then, a second insulation layer 152 covering the first insulation layer 151 may be formed. The first insulation layer 151 may include a silicon oxide layer, a silicon oxide nitride layer, or a metal oxide layer such as an aluminum oxide layer. The second insulation layer 152 may include a silicon oxide layer, a silicon oxide nitride layer, a metal oxide layer such as an aluminum oxide layer, or a low-k oxide layer. Then, an electrode 160 may be formed on the second insulation layer 152. The electrode 160 may contact the top surface of the first core 112 directly and thus, the electrode 160 may be electrically connected to the first core 112. Furthermore, the substrate 100 may be electrically connected to the electrode 160 through the second nanowire 120 and the first core 112.

In the manufacturing method according to this embodiment, other omitted descriptions may be identical to the descriptions of FIGS. 1 and 2.

### Embodiment 3

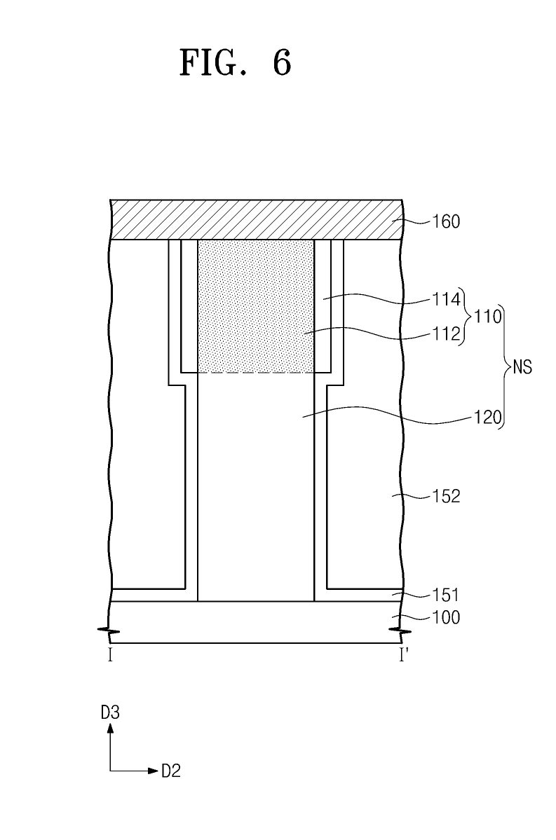

FIG. 6 is a sectional view of a semiconductor device taken along the line I-I′ of FIG. 1 according to another embodiment of the present invention. In this embodiment, the detailed description of the technical features overlapping those described with reference to FIGS. 1 and 4 are omitted and the differences will be described in detail. It is possible to provide the same reference numerals with respect to the same configuration of the above-mentioned semiconductor device according to an embodiment of the present invention.

Referring to FIGS. 1 and 6, a plurality of nanowire structures NS may be disposed on the substrate 100 having a first conductive type. Each of the nanowire structures NS may include a sequentially-stacked second nanowire 120 and first nanowire 110. The second nanowire 120 may have a cylindrical form extending in a third direction D3 on the top surface of the substrate 100. The third direction D3 may be a direction perpendicular to the top surface of the substrate 100. Or, the third direction D3 may be a direction of which angle formed with the top surface of the substrate 100 is close to the verticality. The second nanowire 120 may be interposed between the substrate 100 and the first nanowire 110.

The first nanowire 110 may extend from the top surface of the second nanowire 120 in the third direction D3. The first nanowire 110 may include a first core 112 and a first shell 114 covering the sidewall of the first core 112. At this point, the first core 112 and the second nanowire 120 may constitute one body. That is, the first core 112 may be an upper portion of the second nanowire 120. Accordingly, the diameter of the first core 112 may be substantially identical to the diameter of the second nanowire 120. The diameter of the first nanowire 110 may be greater than the diameter of the second nanowire 120. From the plane perspective, the first nanowire 110 may overlap the second nanowire 120 vertically. Furthermore, the first core 112 and the second nanowire 120 may include the same second intrinsic semiconductor.

In this embodiment, other omitted descriptions may be identical to the descriptions of FIGS. 1, 2, and 4.

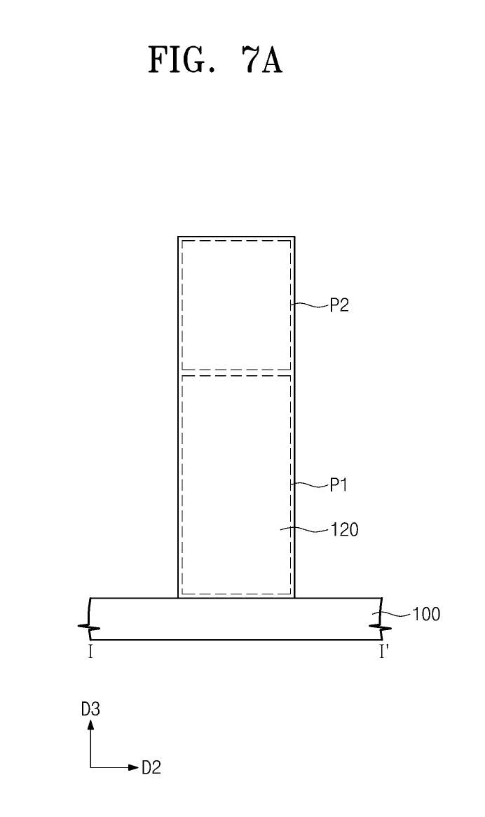

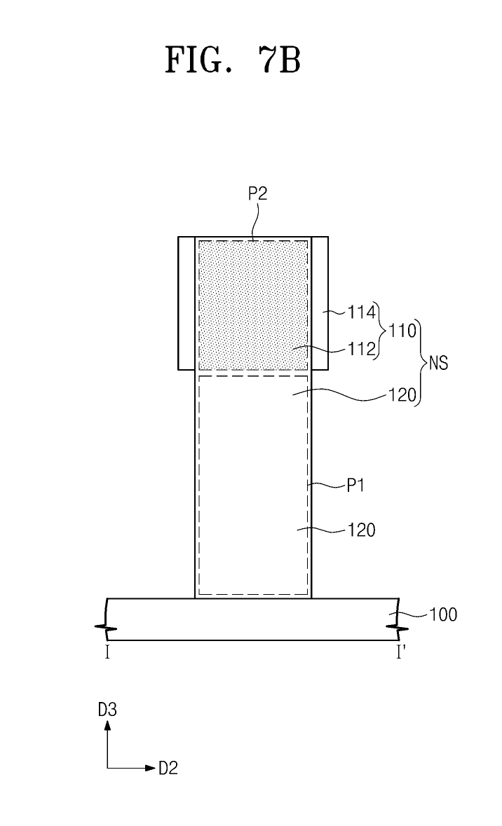

FIGS. 7A and 7B describe a method of manufacturing a semiconductor device according to another embodiment of the present invention and are sectional views taken along the line I-I′ of FIG. 1. In this manufacturing method of this embodiment, the detailed descriptions of the technical features overlapping those of the manufacturing method described with reference to FIGS. 3A, 3B, and 5A to 5C are omitted and the differences will be described in detail.

Referring to FIGS. 1 and 7A, a substrate 100 doped with a first conductive type may be provided. A second nanowire 120 extending in a third direction D3 perpendicular to the top surface of the substrate 100 may be formed on the substrate 100. This may be identical to the formation method of the first core 112 described with reference to FIGS. 1 and 3A. The second nanowire 120 may include a first part P1 adjacent to the substrate 100 and a second part P2 on the first part P1. The second nanowire 120 may include a second intrinsic semiconductor.

Referring to FIGS. 1 and 7B, a first shell 114 may be formed from the sidewall of the second part P2. The first shell 114 may grow in directions parallel to the top surface of the substrate 100. That is, it may be seen that the first shell 114 is formed on only the upper sidewall of the first core 112 in forming the first shell 114 described with reference to FIGS. 1 and 3B. As the first shell 114 is formed, the second part P2 may have a second conductive type opposite to the first conductive type. Therefore, a first core 112 having the second conductive type may be formed from the second part P2.

The formed first core 112 and the formed first shell 114 may define a first nanowire 110. The sequentially-stacked second nanowire 120 and first nanowire 110 may define a nanowire structure NS. Although only the formation process of the one nanowire structure NS is shown through FIGS. 7A and 7B, a plurality of nanowire structures NS may be formed on the substrate 100 at the same time.

In the manufacturing method according to this embodiment, other omitted descriptions may be identical to the descriptions of FIGS. 1, 2, 3A, and 3B, and FIG. 5A to FIG. 5C.

### Embodiment 4

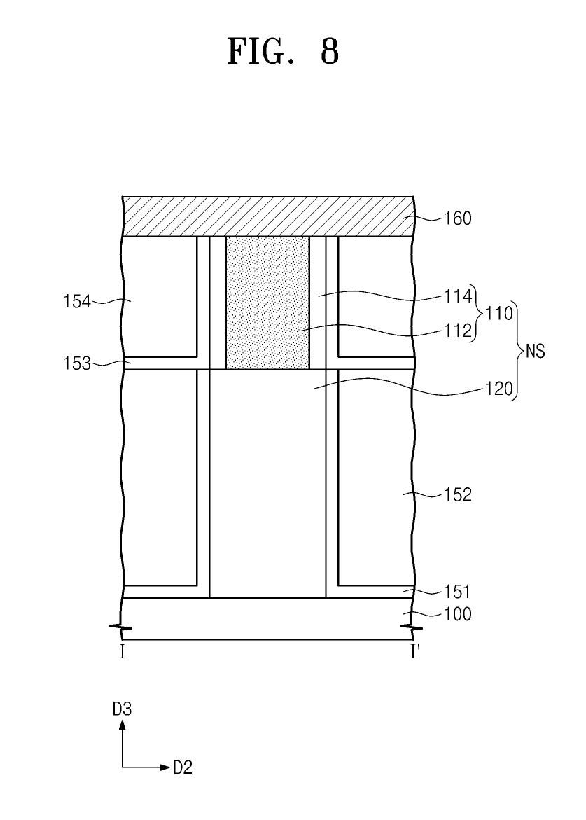

FIG. 8 is a sectional view of a semiconductor device taken along the line I-I′ of FIG. 1 according to another embodiment of the present invention. In this embodiment, the detailed description of the technical features overlapping those described with reference to FIGS. 1 and 4 are omitted and the differences will be described in detail. It is possible to provide the same reference numerals with respect to the same configuration of the above-mentioned semiconductor device according to an embodiment of the present invention.

Referring to FIGS. 1 and 8, a plurality of nanowire structures NS may be disposed on the substrate 100 having a first conductive type. Each of the nanowire structures NS may include a sequentially-stacked second nanowire 120 and first nanowire 110. The second nanowire 120 may have a cylindrical form extending in a third direction D3 on the top surface of the substrate 100. The third direction D3 may be a direction perpendicular to the top surface of the substrate 100. Or, the third direction D3 may be a direction of which angle formed with the top surface of the substrate 100 is close to the verticality. The second nanowire 120 may be interposed between the substrate 100 and the first nanowire 110.

A first insulation layer 151 covering the top surface of the substrate 100 and the sidewall of the second nanowire 120 may be disposed. The top surface of the first insulation layer 151 may be coplanar with the top surface of the second nanowire 120. The first insulation layer 151 may include a silicon oxide layer, a silicon oxide nitride layer, or a metal oxide layer such as an aluminum oxide layer.

A second insulation layer 152 covering the first insulation layer 151 may be disposed. Although not shown in the drawing, the second insulation layer 152 may fill an empty space between the second nanowires 120. The top surface of the second insulation layer 152 may be coplanar with the top surface of the second nanowire 120. The second insulation layer 152 may include a silicon oxide layer, a silicon oxide nitride layer, a metal oxide layer such as an aluminum oxide layer, or a low-k oxide layer. As one example, the low-k oxide layer may include a silicon oxide layer doped with carbon such as SiCOH.

The first nanowire 110 may extend from the top surface of the second nanowire 120 in the third direction D3. The first nanowire 110 may include a first core 112 and a first shell 114 covering the sidewall of the first core 112. The bottom surface of the first core 112 and the bottom surface of the first shell 114 may be disposed on the same level as the top surfaces of the first and second insulation layers 151 and 152.

A third insulation layer 153 covering the top surfaces of the first and second insulation layers 151 and 152 and the sidewall of the first shell 114 may be disposed. The third insulation layer 153 may include a silicon oxide layer, a silicon oxide nitride layer, or a metal oxide layer such as an aluminum oxide layer.

A fourth insulation layer 154 covering the third insulation layer 153 may be disposed. Although not shown in the drawing, the fourth insulation layer 154 may fill an empty space between the first nanowires 110. The top surface of the fourth insulation layer 154 may be coplanar with the top surface of the first nanowire 110. The fourth insulation layer 154 may include a silicon oxide layer, a silicon oxide nitride layer, a metal oxide layer such as an aluminum oxide layer, or a low-k oxide layer. As one example, the low-k oxide layer may include a silicon oxide layer doped with carbon such as SiCOH.

An electrode 160 may be disposed on the first nanowire 110. That is, the electrode 160 may be disposed on the fourth insulation layer 154 and the nanowire structures NS. The electrode 160 may contact the top surface of the first core 112 directly and thus, the electrode 160 may be electrically connected to the first core 112.

In this embodiment, other omitted descriptions may be identical to the descriptions of FIGS. 1, 2, and 4.

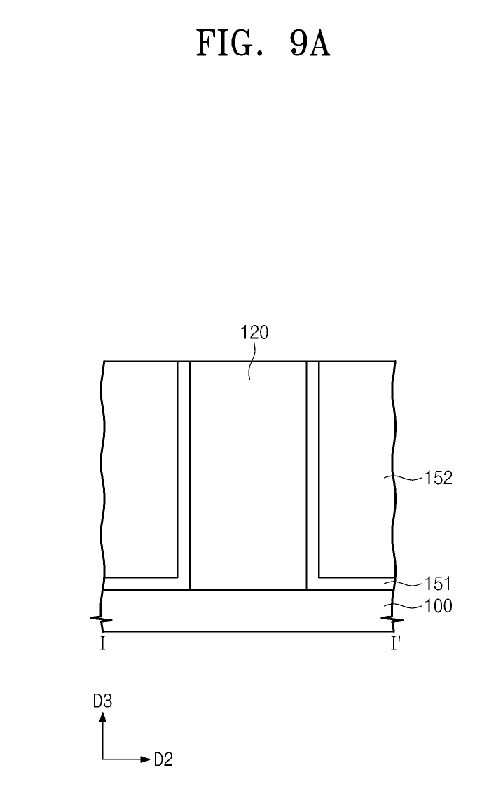

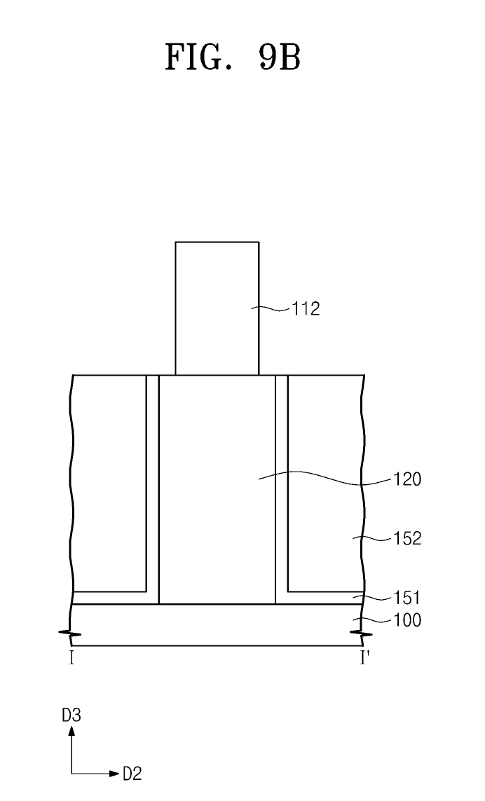

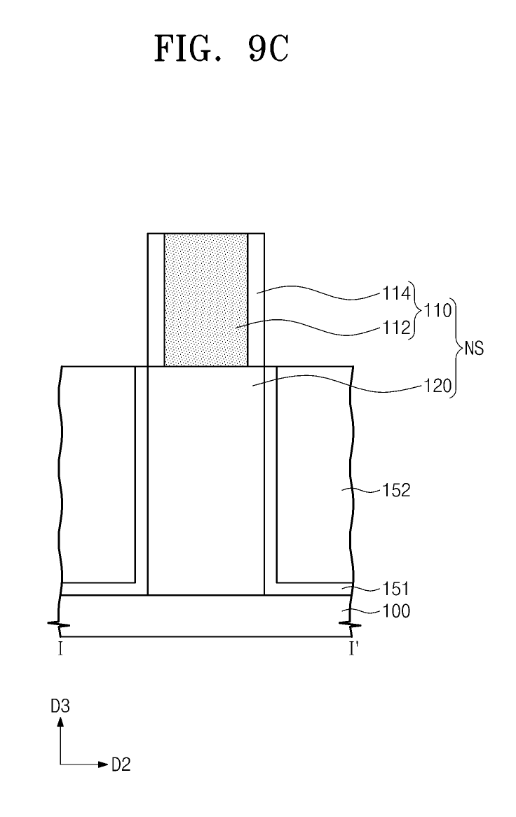

FIGS. 9A to 9C describe a method of manufacturing a semiconductor device according to another embodiment of the present invention and are sectional views taken along a line I-I′ of FIG. 1. In this manufacturing method of this embodiment, the detailed descriptions of the technical features overlapping those of the manufacturing method described with reference to FIGS. 3A, 3B, and 5A to 5C are omitted and the differences will be described in detail.

Referring to FIGS. 1 and 9A, a substrate 100 doped with a first conductive type may be provided. A second nanowire 120 extending in a third direction D3 perpendicular to the top surface of the substrate 100 may be formed on the substrate 100. The second nanowire 120 may include the same second intrinsic semiconductor as a first core 112 described later. Or, the second nanowire 120 may include a different third intrinsic semiconductor than the second intrinsic semiconductor (see 5A).

A first insulation layer 151 covering the top surface of the substrate 100, the sidewall of the second nanowire 120, and the sidewall of the first shell 114 may be formed. Then, a second insulation layer 152 covering the first insulation layer 151 may be formed. The first insulation layer 151 may include a silicon oxide layer, a silicon oxide nitride layer, or a metal oxide layer such as an aluminum oxide layer. The second insulation layer 152 may include a silicon oxide layer, a silicon oxide nitride layer, a metal oxide layer such as an aluminum oxide layer, or a low-k oxide layer.

The second insulation layer 152 and the first insulation layer 151 may be planarized. Through the planarization process, the top surface of the second insulation layer 152 may be coplanar with the top surface of the first insulation layer 151 and the top surface of the second nanowire 120. Therefore, the top surface of the first nanowire 110 may be exposed.

Referring to FIGS. 1 and 9B, a first core 112 extending in the third direction D3 may be formed on the first nanowire 110. The forming of the first core 112 may include growing a second intrinsic semiconductor in the third direction D3 on the exposed top surface of the first nanowire 110.

Referring to FIGS. 1 and 9C, a first shell 114 may be formed from the sidewall of the first core 112. The first shell 114 may grow in directions parallel to the top surface of the substrate 100. As the first shell 114 is formed, the first core 112 may have a second conductive type opposite to the first conductive type.

The formed first core 112 and the formed first shell 114 may define a first nanowire 110. The sequentially-stacked second nanowire 120 and first nanowire 110 may define a nanowire structure NS. Although only the formation process of the one nanowire structure NS is shown through FIGS. 9A to 9C, a plurality of nanowire structures NS may be formed on the substrate 100 at the same time.

Again, referring to FIGS. 1 and 8, a third insulation layer 153 covering the top surface of the second insulation layer 152 and the sidewall of the first shell 114 may be formed. The third insulation layer 153 may include a silicon oxide layer, a silicon oxide nitride layer, or a metal oxide layer such as an aluminum oxide layer. Then, a fourth insulation layer 154 covering the third insulation layer 153 may be formed. The fourth insulation layer 154 may include a silicon oxide layer, a silicon oxide nitride layer, a metal oxide layer such as an aluminum oxide layer, or a low-k oxide layer. The fourth insulation layer 154 and the third insulation layer 153 may be planarized. Through the planarization process, the top surface of the fourth insulation layer 154 may be coplanar with the top surface of the third insulation layer 153 and the top surface of the first nanowire 110. Therefore, the top surface of the first core 112 may be exposed.

Then, an electrode 160 may be formed on the fourth insulation layer 154. The electrode 160 may contact the top surface of the first core 112 directly and thus, the electrode 160 may be electrically connected to the first core 112.

In the manufacturing method according to this embodiment, other omitted descriptions may be identical to the descriptions of FIGS. 1, 2, 3A, and 3B, and FIG. 5A to FIG. 5C.

### Embodiment 5

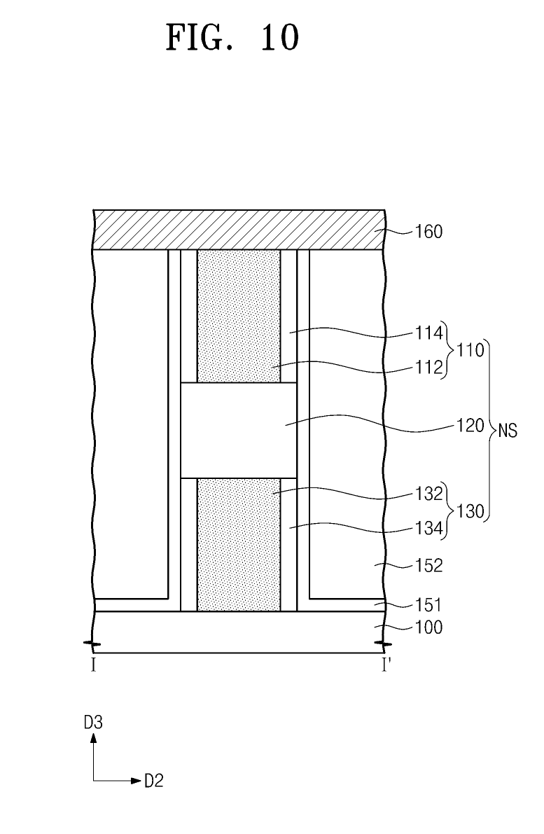

FIG. 10 is a sectional view of a semiconductor device taken along the line I-I′ of FIG. 1 according to another embodiment of the present invention. In this embodiment, the detailed description of the technical features overlapping those described with reference to FIGS. 1 and 4 are omitted and the differences will be described in detail. It is possible to provide the same reference numerals with respect to the same configuration of the above-mentioned semiconductor device according to an embodiment of the present invention.

Referring to FIGS. 1 and 10, a plurality of nanowire structures NS may be disposed on the substrate 100 having a first conductive type. Each of the nanowire structures NS may include a sequentially-stacked third nanowire 130, second nanowire 120, and first nanowire 110. The third nanowire 130 may have a cylindrical form extending in a third direction D3 on the top surface of the substrate 100. The third direction D3 may be a direction perpendicular to the top surface of the substrate 100. Or, the third direction D3 may be a direction of which angle formed with the top surface of the substrate 100 is close to the verticality. The third nanowire 130 may be interposed between the substrate 100 and the second nanowire 120.

The third nanowire 130 may include a second core 132 and a second shell 134 covering the sidewall of the second core 132. The second core 132 may have a cylindrical form extending from the top surface of the substrate 100 in the third direction D3. The second shell 134 may have a pipe shape covering the sidewall of the second core 132 and extending from the top surface of the substrate 100 in the third direction D3. The top surface of the second shell 134 may be coplanar with the top surface of the second core 132. The bottom surface of the second shell 134 may be coplanar with the bottom surface of the second core 132. From the plane perspective, the second core 132 may have a circular form and the second shell 134 may have a donut shape surrounding the frame of the second core 132.

The diameter of the third nanowire 130 may be substantially identical to the diameter of the second nanowire 120. However, the diameter of the second core 132 may be less than the diameter of the second nanowire 120. From the plane perspective, the third nanowire 130 may overlap the second nanowire 120 and the first nanowire 110 vertically.

The second shell 134 may include the same second intrinsic semiconductor as the first core 112. Or, the second shell 134 may include a different forth intrinsic semiconductor than the second intrinsic semiconductor. In more detail, the fourth intrinsic semiconductor may include an elemental semiconductor such as Si and Ge. Or, the fourth intrinsic semiconductor may include a compound semiconductor such as GaAs, GaP, GaSb, InP, InAs, InSb, ZnSe, ZnTe, CdSe, or CdTe. The second core 132 may include the same first intrinsic semiconductor as the first shell 114. Or, the second core 132 may include a fifth intrinsic semiconductor having a bandgap different from that of the fourth intrinsic semiconductor. Besides that, the fifth intrinsic semiconductor may be described identical to the fourth intrinsic semiconductor.

The second core 132 and the second shell 134 may not be doped with impurities. However, the second core 132 may have the same first conductive type as the substrate 100 by the second shell 134. That is, the second core 132 may have the first conductive type by a staggered heterojunction of the second intrinsic semiconductor and the first intrinsic semiconductor or a staggered heterojunction of the fourth intrinsic semiconductor and the fifth intrinsic semiconductor.

In this embodiment, the second core 132 may include Si and the second shell 134 may include Ge. At this point, the second core 132 may have an n-type by a staggered heterojunction of Si and Ge. In this case, the substrate 100 may be a substrate doped with an n-type. On the other hand, the second core 132 may include Ge and the second shell 134 may include Si. At this point, the second core 132 may have a p-type by a staggered heterojunction of Ge and Si. In this case, the substrate 100 may be a substrate doped with a p-type.

The first insulation layer 151 may cover both the sidewalls of the first nanowire 110 and the second nanowire 120 and the sidewall of the third nanowire 130. The electrode 160 may contact the top surface of the first core 112 directly and thus, the electrode 160 may be electrically connected to the first core 112. Furthermore, the substrate 100 may be electrically connected to the electrode 160 through the second core 132, the second nanowire 120, and the first core 112. Thus, a p-i-n junction or an n-i-p junction may be formed through an electrical connection between the substrate 100, the second core 132, the second nanowire 120, and the first core 112. The second nanowire 120 may form a depletion region between the second core 132 and the first core 112.

In this embodiment, other omitted descriptions may be identical to the descriptions of FIGS. 1, 2, and 4.

### Embodiment 6

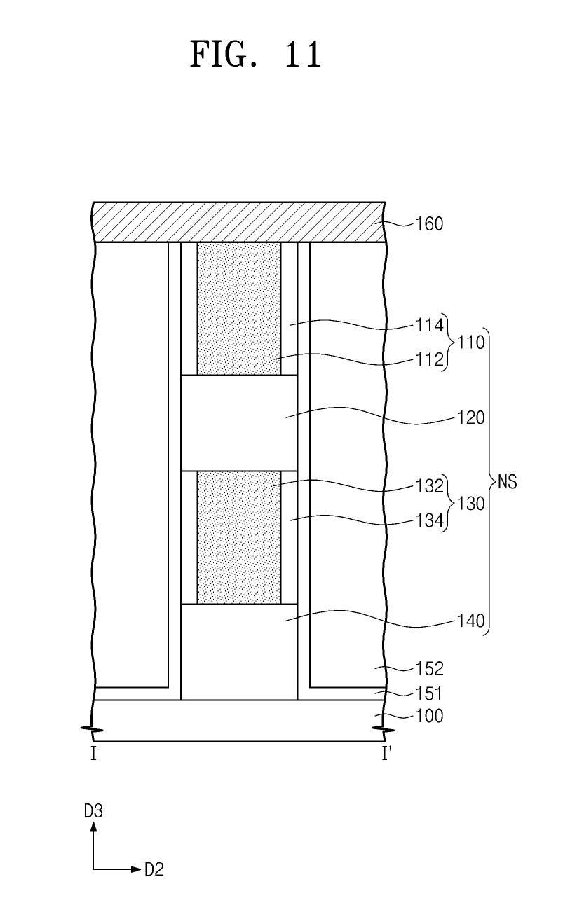

FIG. 11 is a sectional view of a semiconductor device taken along the line I-I′ of FIG. 1 according to another embodiment of the present invention. In this embodiment, the detailed description of the technical features overlapping those described with reference to FIGS. 1 and 10 are omitted and the differences will be described in detail. It is possible to provide the same reference numerals with respect to the same configuration of the above-mentioned semiconductor device according to an embodiment of the present invention.

Referring to FIGS. 1 and 11, a plurality of nanowire structures NS may be disposed on the substrate 100 having a first conductive type. Each of the nanowire structures NS may include a sequentially-stacked fourth nanowire 140, third nanowire 130, second nanowire 120, and first nanowire 110. The fourth nanowire 140 may have a cylindrical form extending in a third direction D3 on the top surface of the substrate 100. The third direction D3 may be a direction perpendicular to the top surface of the substrate 100. Or, the third direction D3 may be a direction of which angle formed with the top surface of the substrate 100 is close to the verticality. The fourth nanowire 140 may be interposed between the substrate 100 and the third nanowire 130.

Unlike the third nanowire 130 or the first nanowire 110, the fourth nanowire 140 may not include an additional core and shell. That is, the fourth nanowire 140 may be formed of one intrinsic semiconductor. The fourth nanowire 140 may include the same second intrinsic semiconductor as the first core 112. Or, the fourth nanowire 140 may include a different sixth intrinsic semiconductor than the second intrinsic semiconductor. In more detail, the sixth intrinsic semiconductor may include an elemental semiconductor such as Si and Ge. Or, the sixth intrinsic semiconductor may include a compound semiconductor such as GaAs, GaP, GaSb,

InP, InAs, InSb, ZnSe, ZnTe, CdSe, or CdTe. Besides that, the fourth nanowire 140 may be identical to the second nanowire 120 described with reference to FIG. 4.

The third nanowire 130 may extend from the top surface of the fourth nanowire 140 in the third direction D3. The third nanowire 130 may include a second core 132 and a second shell 134 covering the sidewall of the second core 132. The diameter of the third nanowire 130 may be substantially identical to the diameter of the fourth nanowire 140. From the plane perspective, the third nanowire 130 may overlap the fourth nanowire 140 vertically.

Unlike the second core 132 described with reference to FIG. 10, the second core 132 may have a second conductive type opposite to a conductive type of the substrate 100. For example, the second core 132 may include Si and the second shell 134 may include Ge. At this point, the second core 132 may have an n-type by a staggered heterojunction of Si and Ge. In this case, the substrate 100 may be a substrate doped with a p-type.

The second nanowire 120 may extend from the top surface of the third nanowire 130 in the third direction D3 and the first nanowire 110 may extend from the top surface of the second nanowire 120 in the third direction D3.

Unlike the first core 112 described with reference to FIG. 4, the first core 112 may have the same first conductive type as the substrate 100. For example, the first core 112 may include Ge and the first shell 114 may include Si. At this point, the first core 112 may have a p-type by a staggered heterojunction of Ge and Si. In this case, the substrate 100 may be a substrate doped with a p-type.

The first insulation layer 151 may cover both the sidewalls of the first nanowire 110, the second nanowire 120, and the third nanowire 130 and the sidewall of the fourth nanowire 140. The electrode 160 may contact the top surface of the first core 112 directly and thus, the electrode 160 may be electrically connected to the first core 112. Furthermore, the substrate 100 may be electrically connected to the electrode 160 through the fourth nanowire 140, the second core 132, the second nanowire 120, and the first core 112. Thus, a p-i-n-i junction or an n-i-p-i junction may be formed through an electrical connection between the substrate 100, the fourth nanowire 140, the second core 132, the second nanowire 120, and the first core 112. The fourth nanowire 140 may form a depletion region between the substrate 100 and the second core 132. The second nanowire 120 may form a depletion region between the second core 132 and the first core 112.

In this embodiment, other omitted descriptions may be identical to the descriptions of FIGS. 1, 2, and 4.

A semiconductor device according to the above-mentioned embodiments of the present invention may be applied to an optical detector. For example, the substrate 100 according to embodiments of the present invention may be a lower electrode and substrate of an optical detector. Nanowire structures NS according to embodiments of the present invention may be a light absorbing layer of an optical detector. The electrode 160 according to embodiments of the present invention may be an upper electrode of an optical detector.

The optical detector may be an infrared detector. The nanowire structures NS according to various embodiments, for example, each core and shell may include one of Si and Ge, that is, an intrinsic semiconductor. Si and Ge may be more sensitive to infrared compared to other semiconductor elements. Furthermore, the nanowire structures NS are formed with a nano size, they may be suitable for optical detection of wavelengths such as infrared.

In relation to a semiconductor device according to the present invention, by a staggered heterojunction Type II of a core and shell forming a nanowire, without artificial impurity doping, the core may have doping effect. Accordingly, in relation to a vertical type nanowire, it is possible to solve the issues of an impurity segregation or a non-uniform doping distribution due to impurity doping. Furthermore, since the semiconductor device includes the nanowire, charge transfer speed can be improved and device current density can be increased.

Since a semiconductor device according to the present invention is sensitive to infrared, it may be applied to an infrared detection.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A semiconductor device comprising:
a substrate doped with a first conductive type;
a first nanowire protruding on the substrate in a first direction and including a first core and a first shell; and
an electrode being on the first nanowire and directly contacting a top surface of the first core,
wherein
the first shell covers a sidewall of the first core;
the first shell includes a first semiconductor; and
the first core includes a second semiconductor having a different bandgap than the first semiconductor.

2. The semiconductor device according to claim 1, wherein a top surface and a bottom surface of the first shell are coplanar with the top surface and a bottom surface of the first core, respectively.

3. The semiconductor device according to claim 1, further comprising:
a first insulation layer covering the top surface of the substrate and a sidewall of the first nanowire; and
a second insulation layer covering the first insulation layer.

4. The semiconductor device according to claim 1, wherein the first nanowire is undoped or intrinsic in terms of electrical polarity.

5. The semiconductor device according to claim 1, wherein the first core is connected to the substrate to form a p-n junction or an n-p junction.

6. The semiconductor device according to claim 1, further comprising a second nanowire protruding on the substrate in the first direction and interposed between the substrate and the first nanowire,
wherein the second nanowire overlaps the first nanowire from the plane perspective; and
the second nanowire includes the second semiconductor or a third semiconductor different from the second semiconductor.

7. The semiconductor device according to claim 6, wherein a diameter of the first core is substantially identical or similar to a diameter of the second nanowire.

8. The semiconductor device according to claim 6, wherein the first core and the second nanowire constitute one body.

9. The semiconductor device according to claim 6, further comprising a third nanowire protruding on the substrate in the first direction, interposed between the substrate and the second nanowire, and including a second core directly contacting the second nanowire and a second shell,
wherein
the third nanowire overlaps the first and second nanowires from the plane perspective;
the second shell covers a sidewall of the second core;
the second shell includes the second semiconductor or a fourth semiconductor different from the second semiconductor;
the second core includes the first semiconductor or a fifth semiconductor having a different bandgap than the fourth semiconductor; and
the second core has the first conductive type by a heterojunction of the first semiconductor and the second semiconductor or a heterojunction of the fourth semiconductor and the fifth semiconductor.

10. The semiconductor device according to claim 1, wherein an angle formed between the first direction and a top surface of the substrate is vertical or close to verticality.

11. The semiconductor device according to claim 1, wherein the first core has a second conductive type by a heterojunction of the first semiconductor and the second semiconductor.

12. A semiconductor device comprising:
a substrate doped with a first conductive type;
first, second, third, and fourth nanowires sequentially stacked on the substrate; and
an electrode disposed on the fourth nanowire to be electrically connected to the substrate,
wherein
each of the first, second, third, and fourth nanowires includes the same or different semiconductor;
the second nanowire includes a first core having a second conductive type and a first shell covering a sidewall of the first core; and
the fourth nanowire includes a second core having the first conductive type and a second shell covering a sidewall of the second core.

13. The semiconductor device according to claim 12, wherein
the first core has the second conductive type by a heterojunction with the first shell;
the second core has the first conductive type by a heterojunction with the second shell; and
the first, second, third, and fourth nanowires are undoped or intrinsic in terms of electrical polarity.

14. A method of manufacturing a semiconductor device, the method comprising:
providing a substrate doped with a first conductive type;
forming a first core, on the substrate, extending in a first direction of which angle formed with a top surface of the substrate is vertical or close to verticality; and
forming a first shell extending from a sidewall of the first core in a second direction parallel to the top surface of the substrate and perpendicular to the first direction,
wherein
the forming of the first shell includes glowing a first semiconductor to cover a sidewall of the first core without impurity doping; and
the forming of the first core includes growing, on the substrate, a second semiconductor having a different bandgap than the first semiconductor without impurity doping.

15. The method according to claim 14, wherein the forming of the first core and the first shell comprises growing the first core and the first shell into a Vapor Liquid Solid (VLS) mechanism through a chemical vapor deposition process.

16. The method according to claim 14, wherein the forming of the first insulation layer covering the top surface of the substrate and the sidewall of the first shell comprises:
forming a second insulation layer covering the first insulation layer;
planarizing the second insulation layer to allow a top surface of the second insulation layer to be coplanar with a top surface of the first core and a top surface of the first shell; and
forming an electrode on the second insulation layer to be electrically connected to the first core.

17. The method according to claim 14, further comprising forming a first nanowire extending in the first direction on the substrate, wherein the forming of the first core includes growing the second semiconductor in the first direction on the first nanowire.

18. The method according to claim 17, further comprising:
forming a first insulation layer covering a top surface of the substrate and a sidewall of the first nanowire;
forming a second insulation layer covering the first insulation layer;
planarizing the second insulation layer to allow a top surface of the second insulation layer to be coplanar with a top surface of the first nanowire,
wherein the forming of the first core includes growing the second semiconductor in the first direction, on the exposed top surface of the first nanowire.

19. The method according to claim 14, wherein the forming of the first shell comprises growing the first semiconductor in the second direction on a partial sidewall of the first core and the partial sidewall of the first core is a sidewall of an upper portion of the first core.
